(19) United States
(12) Patent Application Publication
(10) Pub. No.: US 2012/0162926 A1
(43) Pub. Date: Jun. 28, 2012

(54) SLIDING MODULE FOR ELECTRONIC DEVICE

(75) Inventors: CHAO DUAN, Shenzhen City (CN); CHIA-HUA CHEN, Shindian (TW)

(73) Assignees: FIH (HONG KONG) LIMITED, Kowloon (HK); SHENZHEN FUTAIHONG PRECISION INDUSTRY CO., LTD., ShenZhen City (CN)

(21) Appl. No.: 13/164,301

(22) Filed: Jun. 20, 2011

(30) Foreign Application Priority Data
Dec. 24, 2010 (CN) 201010604300.2

(51) Int. Cl. H05K 7/16; F16C 29/02

(52) U.S. Cl. 361/727; 384/26

(57) ABSTRACT

A sliding module includes a first section, a second section, a hinge module, a sliding member and a pivot body. The hinge module is positioned on the first section. The sliding member is slidably engaged with the first section, and is rotatably connected to the second section. Two ends of the pivot body are respectively connected to the first section and the hinge module. When the sliding member slides relative to the first section, the pivot body moves the second section to rotate relative to the first section to a tilted orientation.

### CROSS-REFERENCE TO RELATED APPLICATIONS

The present application is related to co-pending U.S. patent applications (Attorney Docket No. US37441), each entitled “SLIDING MODULE FOR ELECTRONIC DEVICE”, by Duan et al. These applications have the same assignee as the present application and have been concurrently filed herewith. The above-identified applications are incorporated herein by reference.

### BACKGROUND

1. Technical Field

The present disclosure generally relates to electronic devices, and particularly to a sliding module for an electronic device.

2. Description of Related Art

Portable electronic devices such as mobile phones, laptops, and personal digital assistants (PDAs) are widely used. The sales and use of slide-type portable electronic devices have been on the increase. A slide-type portable electronic device has two housings, of which one slides relative to the other by a slide mechanism to open/close the portable electronic device.

However, the slide-type portable electronic devices typically only allow the two housings to slide parallel to each other. Therefore, when the slide-type portable electronic device is placed horizontally, it can be difficult for users to view a display screen on the housing.

Therefore, there is room for improvement within the art.

### BRIEF DESCRIPTION OF THE DRAWINGS

Many aspects of the tilt mechanism for electronic device can be better understood with reference to the following drawings. The components in the drawings are not necessarily to scale, the emphasis instead being placed upon clearly illustrating the sliding module for electronic device. Moreover, in the drawings, like reference numerals designate corresponding parts throughout the several views.

FIG. 1 is an exploded, isometric view of an electronic device according to an exemplary embodiment.

FIG. 2 is similar to FIG. 1, but shown from another angle.

FIG. 3 is an exploded, isometric view of a hinge assembly used in the electronic device shown in FIG. 1.

FIG. 4 is an isometric view of the electronic device of FIG. 1 in a closed orientation.

FIG. 5 is an isometric view of the electronic device of FIG. 4 during a sliding process.

FIG. 6 is an isometric view of the electronic device of FIG. 4 in an open orientation.

### DETAILED DESCRIPTION

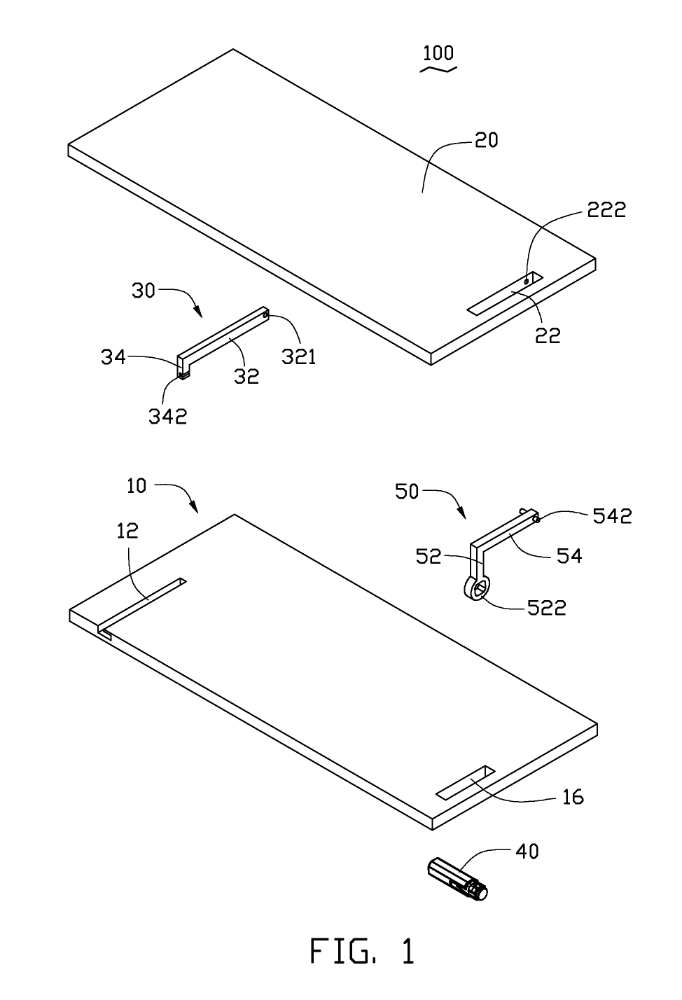

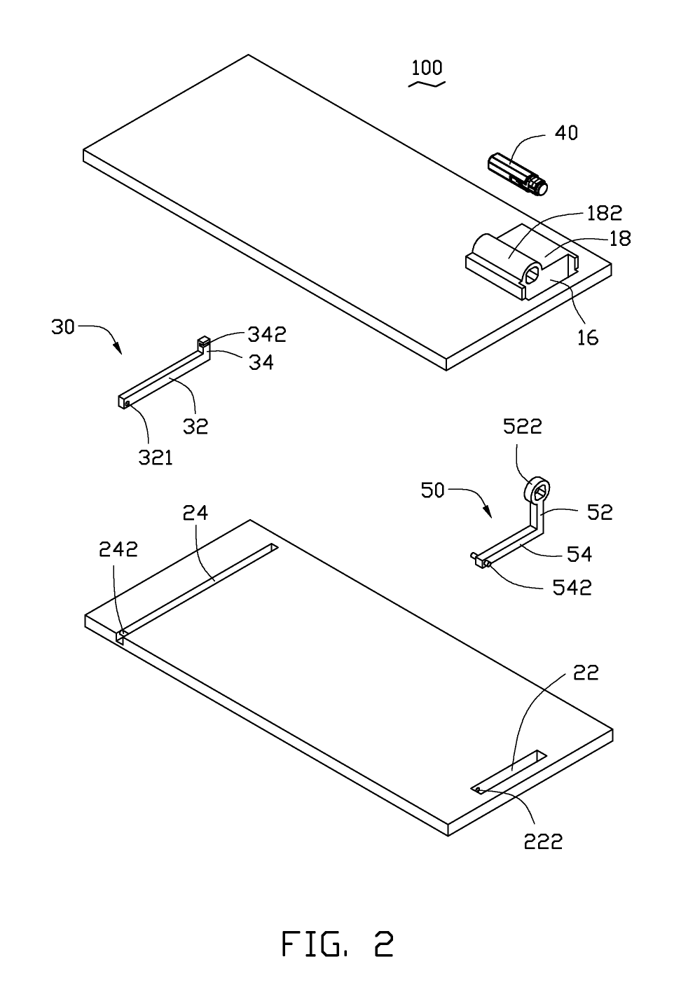

FIG. 1 and FIG. 2 show an exemplary embodiment of a sliding module 100 applied in an electronic device, such as a mobile phone, or a personal digital assistant. The sliding module 100 can be in a closed orientation and a tilted open orientation. The sliding module 100 includes a first section 10, a second section 20, a sliding member 30, a hinge module 40, and a pivot body 50. In the closed orientation, the first section 10 and the second section 20 overlap each other. In the tilted open orientation, the second section 20 tilted relative to the first section 10 for better viewing.

The first section 10 defines an elongated guiding slot 12 and a through hole 16 at opposite sides of one surface thereof. A block 18 is formed on an opposite surface of the first section 10 and is adjacent to the through hole 16. The block 18 has a hinge barrel 182 formed thereon for receiving the hinge module 40.

Referring to FIG. 2, the second section 20 defines a connecting hole 22 and a receiving slot 24 at opposite sides of one surface thereof. Opposite inner walls in the connecting hole 22 respectively define a pivot hole 222. The pivot holes 222 are positioned at one end of the receiving slot 24. A post 242 is formed at one end of the receiving slot 24.

The sliding member 30 includes a connecting arm 32 and an extending arm 34 integrally formed together. The extending arm 34 is perpendicular to the connecting arm 32. One end of the connecting arm 32 defines a post hole 321 for connecting one end of the connecting arm 32 with the post 242. A distal end of the extending arm 34 defines a rail 342 for being slidably received in the guiding slot 12 of the first section 10.

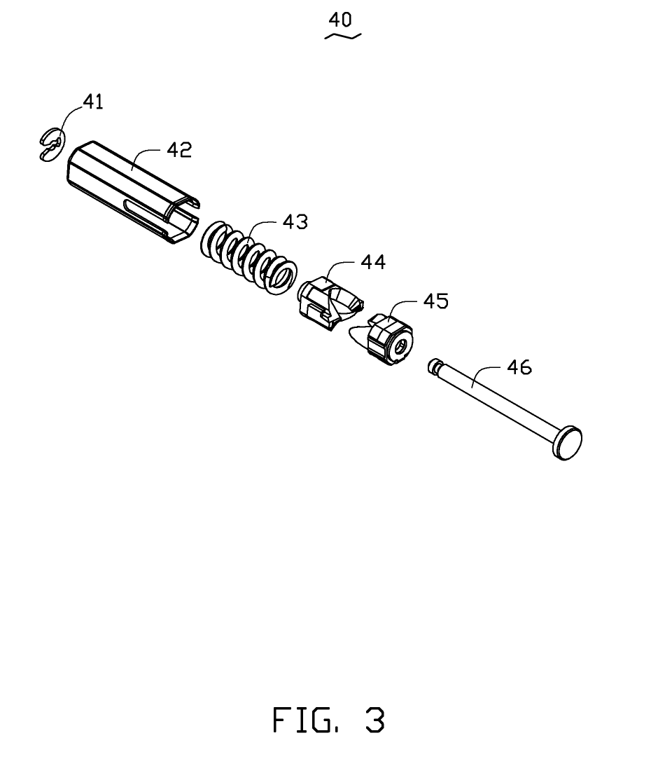

Referring to FIG. 3, the hinge module 40 includes a washer 41, a sleeve 42, a resilient member 43, a cam 44, a follower 45, and a shaft 46. The cam 44, the follower 45, and the resilient member 43 are fitted over the shaft 46, and are received in the sleeve 42. The washer 41 is latched to one end of the shaft 46 with the above elements to assemble a unit. The follower 45 is non-rotatably engaged in the sleeve 42. The sleeve 42 can be inserted into the hinge barrel 182 and cannot rotate relative to the hinge barrel 182. The follower 45 includes peaks and valleys, and the cam 44 can slide over the peaks of the follower 44 to allow the cam 45 to rotate relative to the follower 45.

The pivot body 50 includes a first pivot arm 52 and a second pivot arm 52 perpendicularly connected to the first pivot arm 52. The first pivot arm 52 is connected to the first section 10, and the second pivot arm 54 is connected to the second section 20. The first pivot arm 52 has a knuckle 522 formed on one end thereof. The knuckle 522 is received in the through hole 16 and is aligned with the hinge barrel 182. The cam 45 in the hinge barrel 182 can be inserted into the knuckle 522 and cannot rotate relative to the knuckle 522. The second pivot arm 52 has a pivot pin 542 formed at one end thereof. The pivot pin 542 is rotatably received in the pivot holes 222 in the connecting hole 22.

In assembly, the assembled hinge module 40 is received in the hinge barrel 182 of the first section 10. The sleeve 42 is non-rotatably engaged with the hinge barrel 182. The rail 342 of the sliding member 30 is slidably received in the guiding slot 12. The connecting arm 32 is placed on the surface of the first section 10. Then, the knuckle 522 of the pivot body 50 extends through the through hole 16, and is non-rotatably engaged with the cam 45 of the hinge module 40. The second pivot arm 54 is received in the connecting hole 22. The pivot pin 542 is rotatably received in the pivot holes 222. The connecting arm 32 is received in the receiving slot 24. The post 242 extends through the post hole 321 to connect the sliding member 30 to the second section 20. Accordingly, the sliding module 100 is assembled.

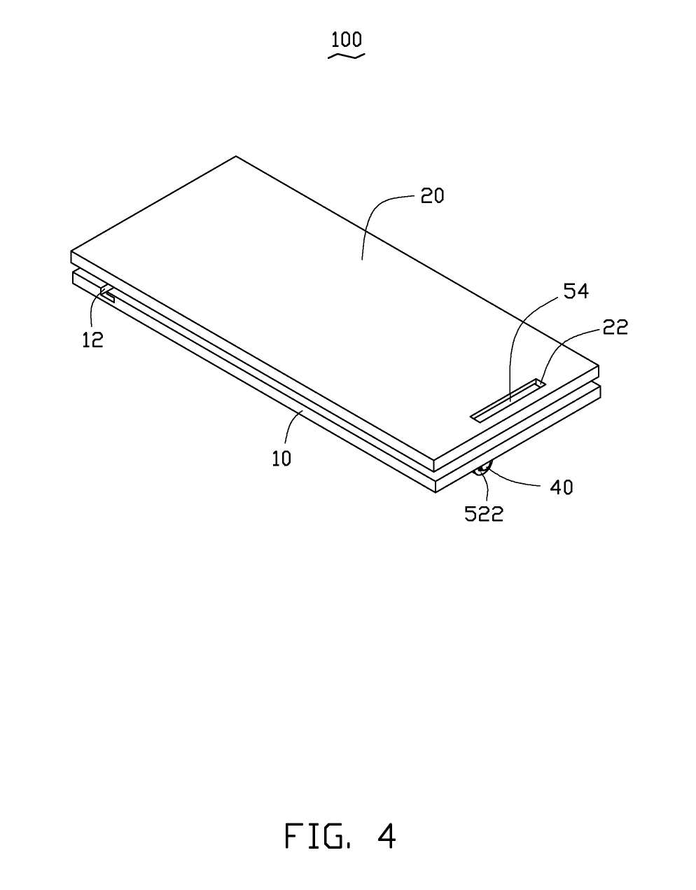

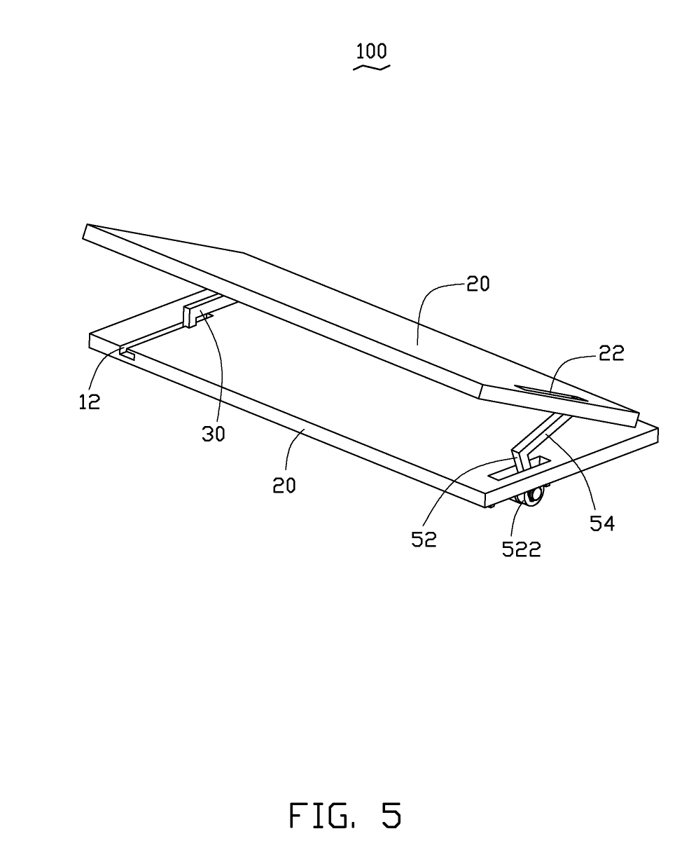

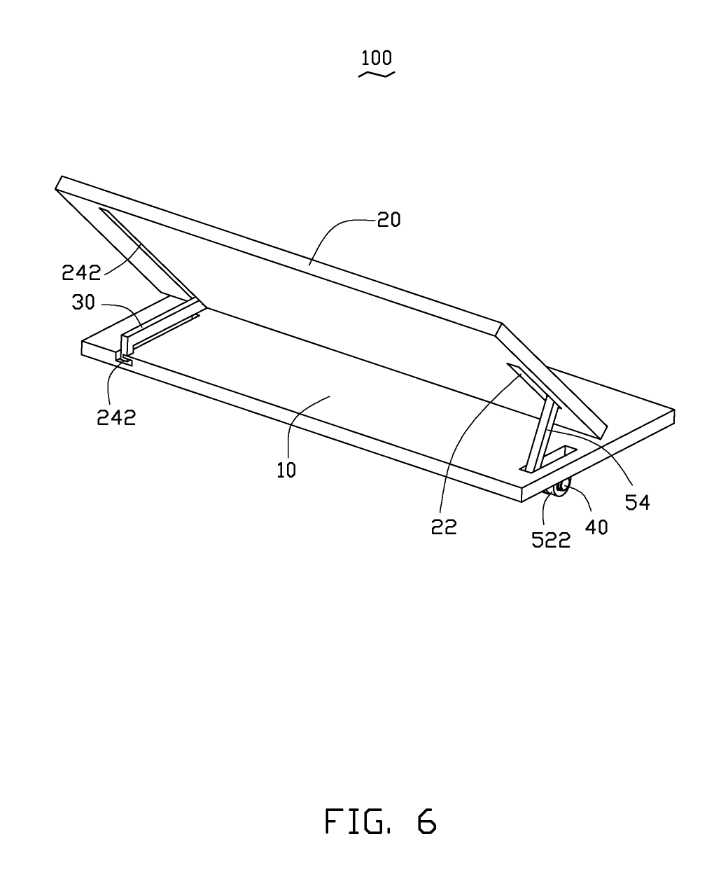

Referring to FIG. 4, when the sliding module 100 is in a closed orientation, the second section 20 is on the first section 10. The pivot body 50 is received in the through hole 16 and the connecting hole 22. Referring to FIGS. 5 and 6, when the sliding module 100 is to be opened, a force is applied to the second section 20 to move the second section 20 away from the first section 10. The sliding member 30 slides along the guiding slot 12 of the first section 10 to force the pivot body 50 to rotate. Thus, the cam 45 is driven to rotate relative to the follower 44. When the cam 45 slides over the peaks of the follower 44, the cam 45 automatically rotates the pivot body 50 until the second section 20 is completely opened relative to the first section 10. The second section 20 is supported in a tilted position relative to the first section 10.

It is to be understood, however, that even through numerous characteristics and advantages of the present disclosure have been set forth in the foregoing description, together with details of the structure and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A sliding module comprising:
a first section;
a second section;
a hinge module positioned on the first section;
a sliding member slidably engaged with the first section, and rotatably connected to the second section; and
a pivot body, two ends of the pivot body respectively connected to the first section and the hinge module;
wherein when the sliding member slides relative to the first section, the pivot body brings the second section to move and rotate relative to the first section in a tilted orientation.

2. The sliding module as claimed in claim 1, wherein the first section defines a guiding slot, and the sliding member includes a rail for slidably received in the guiding slot.

3. The sliding module as claimed in claim 2, wherein the sliding member includes a connecting arm and an extending arm perpendicularly connected to the connecting arm, the connecting arm is connected to the second section, and the rail is formed on one end of the extending arm.

4. The sliding module as claimed in claim 3, wherein one end of the connecting arm defines a post hole, the second section defines a receiving groove, and a post extends through the post hole to connect the connecting arm to the receiving groove.

5. The sliding module as claimed in claim 1, wherein the first section defines a through hole and forms a block, a hinge barrel is formed on the block, one end of the hinge module is received in the hinge barrel, the second section defines a receiving slot, and the pivot body is engaged in the receiving slot and the through hole.

6. The sliding module as claimed in claim 5, wherein the pivot body includes a first pivot arm and a second pivot arm perpendicularly connected to the first pivot arm, the first pivot arm is received in the receiving slot, and the second pivot arm is received in the through hole.

7. An electronic device comprising:
a first section;
a second section;
a hinge module positioned on the first section;
a sliding member slidably engaged with the first section, and rotatably connected to the second section; and
a pivot body, two ends of the pivot body respectively connected to the first section and the hinge module, the pivot body bringing the second section to move and rotate relative to the first section.

8. The electronic device as claimed in claim 7, wherein the first section defines a guiding slot, and the sliding member includes a rail for slidably received in the guiding slot.

9. The electronic device as claimed in claim 8, wherein the sliding member includes a connecting arm and an extending arm perpendicularly connected to the connecting arm, the connecting arm is connected to the second section, and the rail is formed on one end of the extending arm.

10. The electronic device as claimed in claim 9, wherein one end of the connecting arm defines a post hole, the second section defines a receiving groove, and a post extends through the post hole to connect the connecting arm to the receiving groove.

11. The electronic device as claimed in claim 7, wherein the first section defines a through hole and forms a block, a hinge barrel is formed on the block, one end of the hinge module is received in the hinge barrel, the second section defines a receiving slot, and the pivot body is engaged in the receiving slot and the through hole.

12. The electronic device as claimed in claim 11, wherein the pivot body includes a first pivot arm and a second pivot arm perpendicularly connected to the first pivot arm, the first pivot arm is received in the receiving slot, and the second pivot arm is received in the through hole.
